(19) United States
(12) Patent Application Publication
(10) Pub. No.: US 2014/0312349 A1
(43) Pub. Date: Oct. 23, 2014

(54) THIN FILM TRANSISTOR AND MANUFACTURING METHOD THEREOF AND ARRAY SUBSTRATE INCLUDING THE THIN FILM TRANSISTOR

(71) Applicant: Chunsheng Jiang, Beijing (CN)

(72) Inventor: Chunsheng Jiang, Beijing (CN)

(73) Assignee: BOE TECHNOLOGY GROUP CO., LTD., Beijing (CN)

(21) Appl. No.: 13/697,409

(22) PCT Filed: Jul. 17, 2012
(86) PCT No.: PCT/CN2012/078770

§ 371 Date: Nov. 12, 2012

(30) Foreign Application Priority Data
Jul. 25, 2011 (CN) 201110209184.9

(51) Int. Cl. H01L 29/786; H01L 29/66

(52) U.S. Cl. CPC H01L 29/78675; H01L 29/66757
USPC 257/66; 438/166

(57) ABSTRACT

An embodiment of the present invention provides a thin film transistor and a manufacturing method thereof and an array substrate comprising the thin film transistor. The method comprises: depositing an amorphous layer on a substrate, and patterning the amorphous layer so as to form an active layer comprising a source region, a drain region and a channel region; forming a gate insulating layer and a gate electrode above the channel region; depositing an induction metal layer on the substrate on which the gate electrode is formed; doping impurity into the source region and the drain region by an ion implanting process and bombarding part of the induction metal into the source region and the drain region; removing the induction metal layer; performing a thermal treatment to the doped active layer so that the impurity is activated and the metal induced crystallization and the metal induced lateral crystallization occur in the active layer due to the induction metal, converting the amorphous silicon to polysilicon in the source region, the drain region and the channel region of the active layer; and forming a source electrode and a drain electrode.

### TECHNICAL FIELD

Embodiments of the present invention relate to a thin film transistor and a manufacturing method thereof and an array substrate including the thin film transistor.

### BACKGROUND

Metal-induced crystallization (MIC) and metal-induced lateral crystallization (MILC) are methods for manufacturing low temperature poly-silicon (LTPS). Compared with the technologies such as excimer laser annealing (ELA), solid phase crystallization (SPC) and the like in the prior art, MIC and MILC technologies have advantages such as low crystallization temperature, short crystallization duration, and simple manufacturing apparatuses and processes, thus it is adaptive for mass producing.

FIGS. 1 A to 1F are cross-sectional diagrams showing a process for manufacturing the TFT including a polysilicon active layer (polysilicon TFT) by using the MIC and MILC technologies in the prior art. Typically, the process for manufacturing polysilicon TFT in the prior art may comprise the following steps.

Step S1: firstly, forming a buffer layer 2 on a substrate 1 and forming an amorphous layer 3 on the buffer layer 2, and then patterning the amorphous layer 3 so as to form an active layer comprising a source region, a drain region and a channel region (as shown in FIG. 1A);

Step S2: applying a layer of photoresist 4 on the substrate 1 on which the active layer is formed, and removing the photoresist located above the source region and the drain region by developing after exposing the photoresist 4 with a photo mask, and then depositing an induction metal layer 5 (as shown in FIG. 1B);

Step S3: removing the remaining photoresist and keeping the induction metal layer located above the source region and the drain region (as shown in FIG. 1C);

Step S4: performing a first thermal treatment in an annealing furnace so that the metal induced crystallization and the metal induced lateral crystallization occur in the active layer and thus an MIC region 6 and an MILC region 7 are formed (as shown in FIG. 1D);

Step S5: removing the remaining induction metal (as showing in FIG. 1E);

Step S6: depositing a gate insulating layer 8 and a gate metal layer 9, and etching the gate metal layer 9 and the gate insulating layer 8 so as to form a gate electrode (as shown in FIG. 1F);

Step S7: implanting a p-type dopant (e.g., B⁺) or an n-type dopant (e.g., P⁺) into the substrate 1, on which the gate electrode 1 is formed, by using ion implanting technology according to the conductive type of the MOS device (e.g., PMOS or NMOS), and performing a second thermal treatment in the annealing furnace after the ion implanting so as to activate the impurity.

It can be seen that, in the above method for manufacturing the polysilicon TFT, it is required to perform the thermal treatment for two times, i.e., the thermal treatment for crystallization and the thermal treatment for activating the impurity after the ion implanting, thus the duration and the costs required for manufacturing the polysilicon TFT are increased.

### SUMMARY OF THE INVENTION

In one embodiment of the invention, a method for manufacturing a thin film transistor comprising a polysilicon active layer is provided. The method comprises: depositing an amorphous layer on a substrate, and patterning the amorphous layer so as to form an active layer comprising a source region, a drain region and a channel region; forming a gate insulating layer and a gate electrode above the channel region; depositing an induction metal layer on the substrate on which the gate electrode is formed; doping impurity into the source region and the drain region by an ion implanting process and bombarding part of the induction metal into the source region and the drain region; removing the induction metal layer; performing a thermal treatment to the doped active layer so that the impurity is activated and the metal induced crystallization and the metal induced lateral crystallization occur in the active layer due to the induction metal, converting the amorphous silicon to polysilicon in the source region, the drain region and the channel region of the active layer; and forming a source electrode and a drain electrode.

In another embodiment of the invention, a method for manufacturing a thin film transistor comprising a polysilicon active layer is provided. The method comprises: forming a gate electrode and a gate insulating layer on a substrate; forming an amorphous layer on the gate insulating layer, and patterning the amorphous layer so as to form an active layer comprising a source region, a drain region and a channel region; forming a mask above the channel region; depositing an induction metal layer on the substrate on which the mask is formed; doping impurity into the source region and the drain region by an ion implanting process and bombarding part of the induction metal into the source region and the drain region; removing the mask and the induction metal layer; performing a thermal treatment to the doped active layer so that the impurity is activated and the metal induced crystallization and the metal induced lateral crystallization occur in the active layer due to the induction metal, converting the amorphous silicon to polysilicon in the source region, the drain region and the channel region of the active layer; and forming a source electrode and a drain electrode.

In another embodiment of the invention, a thin film transistor comprising a polysilicon active layer is provided. The thin film transistor is manufactured by the method described above.

In another embodiment of the invention, an array substrate is provided. The array substrate comprises the thin film transistor described above.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIGS. 1A to 1F are cross-sectional diagrams showing a process for manufacturing the TFT including a polysilicon active layer in the prior art;

FIG. 2 is a flow diagram showing a method for manufacturing a TFT including a polysilicon active layer in a first embodiment of the invention;

FIGS. 3A to 3F are cross-sectional diagrams showing a process for manufacturing the TFT including a polysilicon active layer in the first embodiment of the invention; and

FIG. 4 is a flow diagram showing a method for manufacturing a TFT including a polysilicon active layer in a second embodiment of the invention.

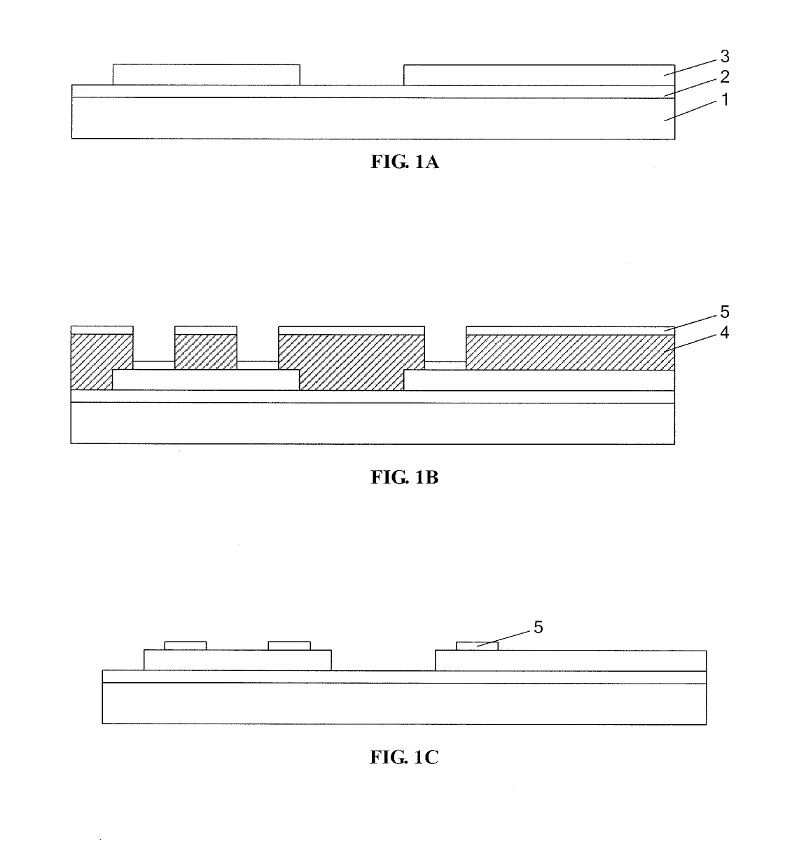

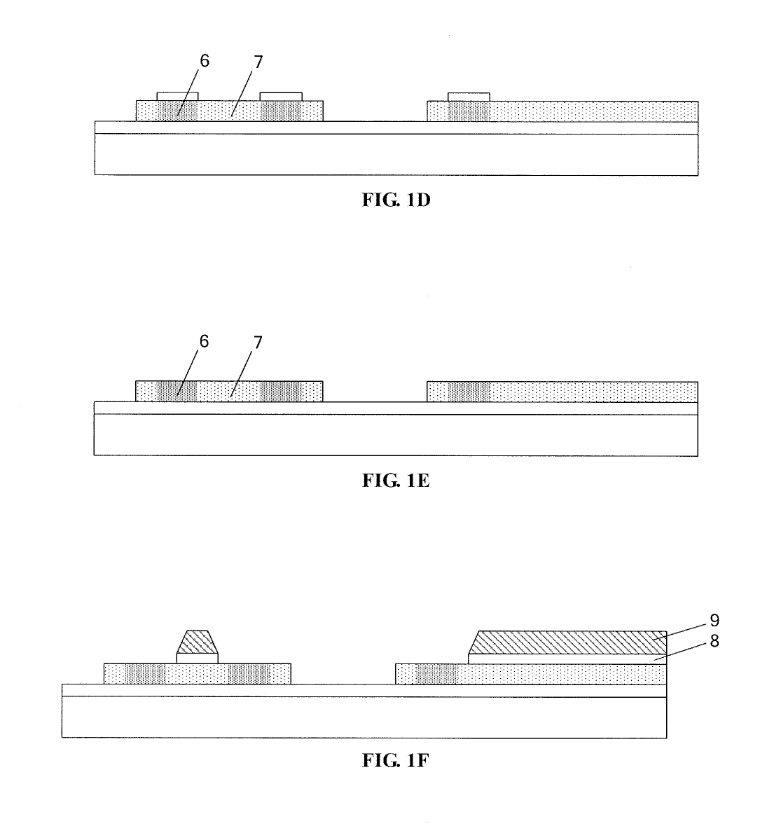

### DESCRIPTION OF THE EMBODIMENTS

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

In embodiments of the invention, a thin film transistor including a polysilicon active layer and a manufacturing method thereof and an array substrate including the thin film transistor are provided, in order to reduce the manufacturing time and costs. The embodiments of the invention will be described below in details with reference to the accompanying drawings.

### First Embodiment

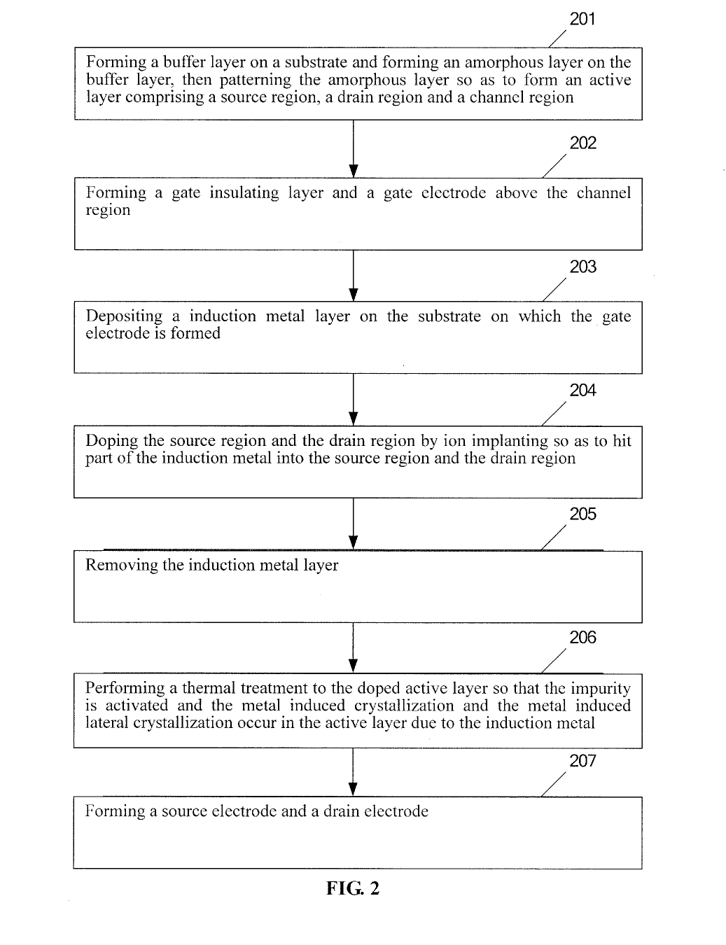

FIG. 2 is a flow diagram showing a method for manufacturing a TFT including a polysilicon active layer in a first embodiment of the invention. The method in this embodiment can be applied for forming a polysilicon TFT having a top-gate structure. In the following, the steps of the method will be described with reference to FIG. 2.

Step 201: forming a buffer layer on a substrate and forming an amorphous layer on the buffer layer, and then patterning the amorphous layer so as to form an active layer comprising a source region, a drain region and a channel region.

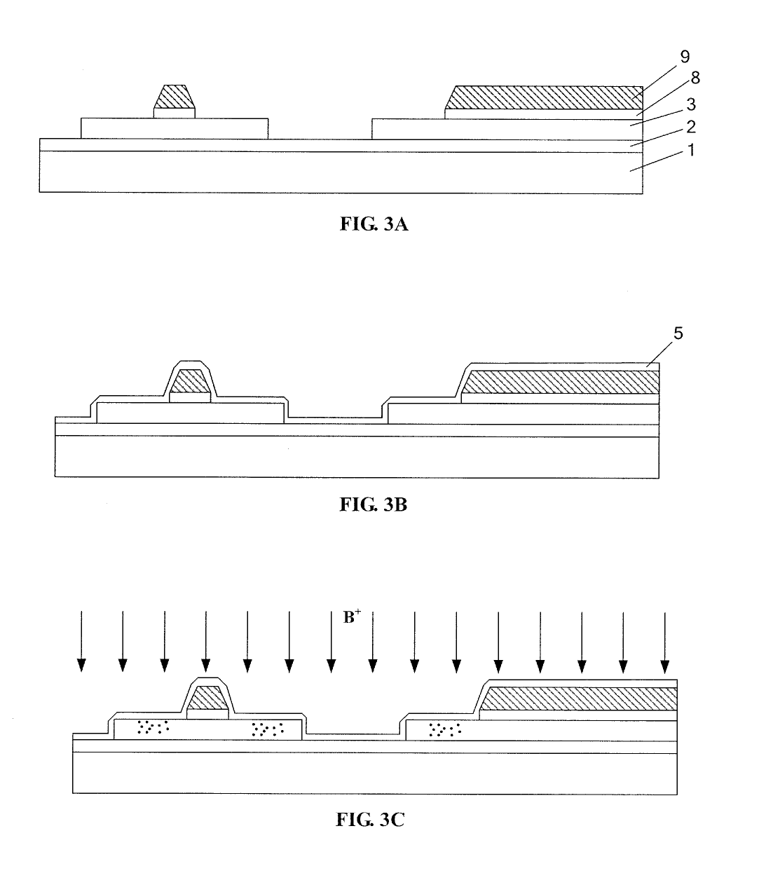

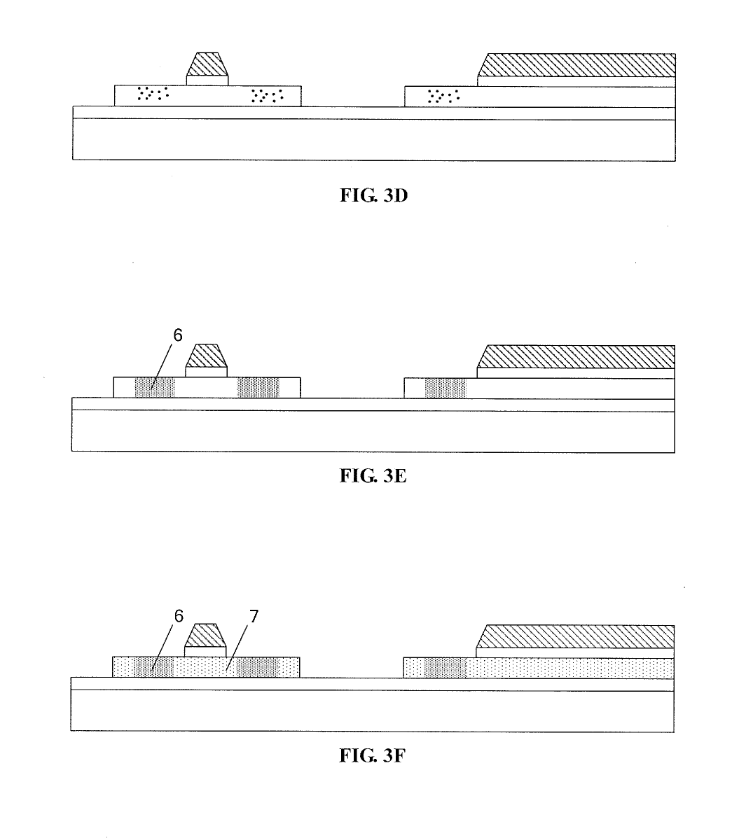

As shown in FIG. 3A, firstly, a buffer layer 2 is formed on a transparent substrate 1 such as a glass substrate and the like subjected to a pre-clearing process, by plasma enhanced chemical vapor deposition (PECVD), low pressure chemical vapor deposition (LPCVD), atmospheric pressure chemical vapor deposition (APCVD), electron cyclotron resonance chemical vapor deposition (ECR-VCD), sputtering and the like, for blocking impurities contained in glass from diffusing into the active layer to be formed subsequently, and thus preventing the threshold voltage, leakage current or other properties of the TFT device from being adversely affected. The buffer layer 2 can be a single layer of silicon oxide, silicon nitride or silicon nitride oxide or a laminated layer thereof For example, the buffer layer 2 has a thickness of 300 Å to 10000 Å, and is deposited at a temperature of 600° C. or lower.

Thereafter, an amorphous layer 3 is deposited on the buffer layer 2 and is patterned by a photolithograph process and an etching process (for example, dry etching) so that the patterned amorphous layer 3 comprises a source region, a drain region and a channel region to form the active layer of the TFT. For example, the active layer has a thickness of 100 Å to 3000 Å, and is formed by PECVD, LPCVD or sputtering at a deposition temperature lower than 600° C.

Step 202: forming a gate insulating layer and a gate electrode above the channel region.

Also as shown in FIG. 3A, firstly, a gate insulating layer 8 is deposited on the active layer by PECVD, LPCVD, APCVD, ECR-CVD or the like. Subsequently, a gate metal layer 9 is deposited on the gate insulating layer 8 by sputtering, thermal evaporation, PECVD, LPCVD, APCVD, ECR-CVD or the like. Next, a photoresist pattern is formed by a photolithograph process and then the gate insulating layer 8 and the gate metal layer 9 are etched by using a method of wet etching or dry etching with the photoresist pattern as a mask so as to pattern the gate insulating layer 8 and the gate metal layer 9. Following the etching, the photoresist pattern is removed.

In one embodiment of the invention, the gate insulating layer 8 has a thickness of 300 Å to 3000 Å, but the invention is not limited hereto. For example, the thickness can be selected properly according to the specific process. The gate insulating layer 8 can be a single layer of silicon oxide, silicon nitride or silicon nitride oxide or a laminated layer thereof, and is deposited at a temperature lower than 600° C. The gate metal layer 9 is made of a conductive material, including a metal (e.g. molybdenum (MO)), a metal alloy (e.g. MO alloy) or doped polysilicon, and has a thickness between 1000 Å and 8000 Å.

Step 203: depositing an induction metal layer on the substrate on which the gate electrode is formed.

In this embodiment, Nickel (Ni) is employed to form the induction metal layer, thus it is possible to obtain better induction effect and better TFT properties. However, the induction metal for forming the induction metal layer is not limited to Ni. For example, the induction metal can be one or more from Ni, Copper (Cu), Gold (Au), Silver (Ag), Aluminum (Al), Cobalt (Co), and chromium (Cr). As shown in FIG. 3B, a Ni thin film 5 can be formed by sputtering, thermal evaporation, PECVD, atomic layer deposition (ATM) or the other similar method with a thickness between 1 Å to 10000 Å. In this embodiment, the Ni thin film 5 is formed by ALD in order to control the thickness of the Ni thin film 5 more accurately.

Step 204: doping impurity into the source region and the drain region by an ion implanting process so as to bombard part of the induction metal into the source region and the drain region;

It is possible to implant a p-type dopant (B⁺) or an n-type dopant (P⁺) according to the conductive type of TFT (PMOS or NMOS). FIG. 3C shows a case where B⁺ is implanted with the gate insulating layer 8 and the gate electrode layer 9 being used as a mask when the TFT is a PMOS device, in which the dose of B⁺ ranges from 1×10¹⁵ to 1×10¹⁶ atoms/cm³. Since the Ni thin film 6 is dense and thin in thickness, the Ni atoms are directed into the source region and the drain region together with the implanted B⁺. The amount of Ni atoms which are bombarded into the amorphous silicon is extremely small with respect to the amount of atoms in the Ni thin film 5. In this manner, the effect of remaining Ni atoms to the channel region is reduced significantly after the crystallization of the amorphous silicon.

The ion implanting is one of the common doping technologies. The available ion implanting technology may include ion implanting with a mass synchrometer, ion-cloud implanting, plasma implanting or solid state diffusion implanting without a mass synchrometer. In this embodiment, the ion-cloud implanting is employed.

Step 205: removing the induction metal layer.

As shown in FIG. 3D, the remaining Ni thin film 5 can be removed by etching after the ion implanting. For example, in this embodiment, the substrate 1 is dipped into 30% H₂SO₄ solution (for about 30 minutes) so as to remove the remaining Ni thin film 5 completely.

Step 206: performing a thermal treatment to the doped active layer so that the impurity is activated and the metal induced crystallization and the metal induced lateral crystallization occur in the active layer due to the induction metal, converting the amorphous silicon to polysilicon in the source region, the drain region and the channel region of the active layer;

As shown in FIGS. 3E and 3F, the substrate 1 is placed into an annealing furnace to be subject to an annealing thermal treatment and thus to complete the activation of the impurity and the crystallization of the amorphous silicon at the same time. For example, the annealing temperature ranges from 400° C. to 600° C., and the annealing time ranges from 1 hour to 3 hours. Since the Ni atoms exist in the source and drain regions, upon performing the thermal treatment, firstly the MIC crystallization is achieved to form the MIC region 6. Following the MIC crystallization of the source and drain region, the MILC crystallization is achieved in the channel region to form the MILC region 7. The active layer of the TFT is converted from amorphous silicon to polysilicon.

Step 207: forming a source electrode and a drain electrode.

Specifically, the step 207 may include depositing a passivation layer on the thermally treated substrate 1; patterning the passivation layer by a photolithograph process and an etching process (e.g. wet etching or dry etching) so that via holes are formed in the passivation layer; and forming a source electrode and a drain electrode which are connected to the source region and the drain region through the via holes respectively.

The first embodiment of the invention is advantageous in the follows aspects.

(1) Since the induction metal is bombarded into the active layer during performing ion implanting, only one thermal treatment to the active layer is required in order to complete the activation of the impurity and the crystallization of the amorphous silicon, and in turn the duration and the costs for manufacturing the polysilicon TFT are reduced;

(2) The amount of the induction metal which is bombarded into the active layer is extremely small, thus it is possible to decrease the amount of the induction metal remaining in the channel region after the crystallization is completed, and in turn to decrease the leakage current of the polysilicon TFT and improve the electrical properties of the polysilicon TFT; and

(3) Since the gate electrode is used as a mask to deposit the induction metal, the number of the photolithograph processes is reduced and in turn the duration and the costs for manufacturing the polysilicon TFT are reduced.

### Second Embodiment

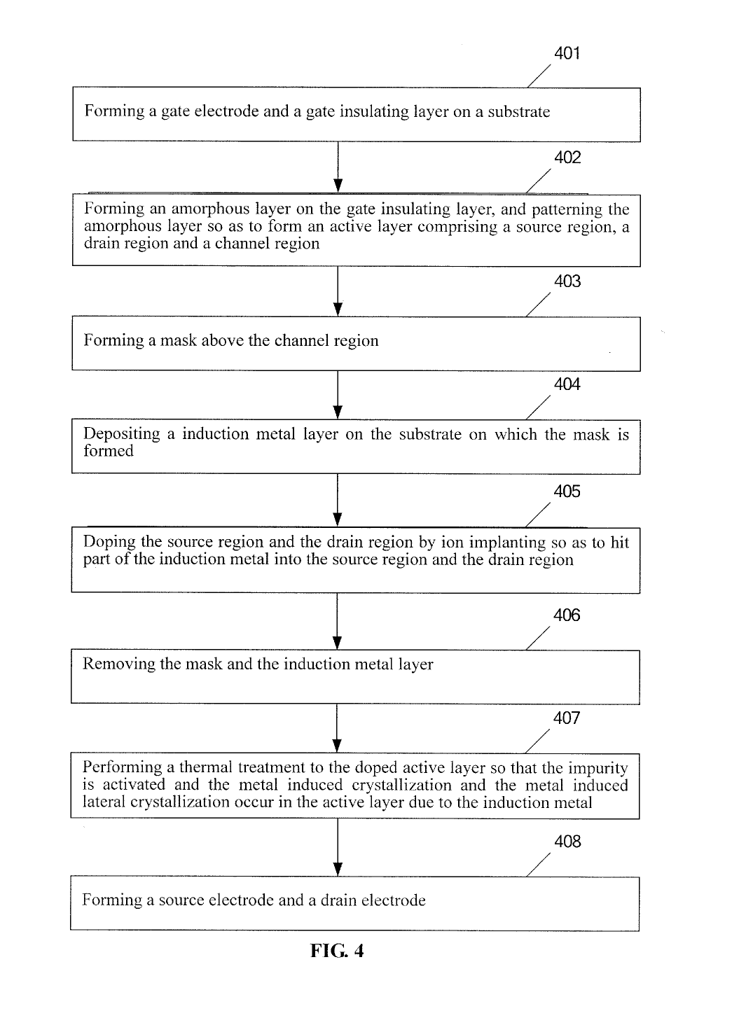

FIG. 4 is a flow diagram showing a method for manufacturing a TFT including a polysilicon active layer in a second embodiment of the invention. The method in this embodiment can be applied for forming a polysilicon TFT having a bottom-gate structure. In the following, the steps of the method will be described with reference to FIG. 4.

Step 401: forming a gate electrode and a gate insulating layer on a substrate.

Firstly, a gate metal layer is deposited on a transparent substrate such as a glass substrate or the like subject to a pre-clearing process, by sputtering, thermal evaporation, PECVD, LPCVD, APCVD, ECR-CVD or the like. Next, a photoresist pattern is formed by using the photolithograph process and then the gate metal layer is etched by using a method of wet etching or dry etching with the photoresist pattern as a mask so as to pattern the gate metal layer to form a gate electrode. Thereafter, a gate insulating layer is deposited on the substrate, on which the gate electrode is formed, by PECVD, LPCVD, APCVD, ECR-CVD or the like.

The gate metal layer is made of a conductive material, including a metal (e.g. molybdenum (MO)), a metal alloy (e.g. MO alloy) or doped polysilicon. For example, the gate metal layer has a thickness between 1000 Å and 8000 Å. In one embodiment of the invention, the gate insulating layer has a thickness of 300 Å to 3000 Å, but the invention is not limited hereto. For example, the thickness can be selected properly according to the specific process. The gate insulating layer can be a single layer of silicon oxide, silicon nitride or silicon nitride oxide or a laminated layer thereof, and is deposited at a temperature lower than 600° C.

Step 402: forming an amorphous layer on the gate insulating layer, and then patterning the amorphous layer so as to form an active layer comprising a source region, a drain region and a channel region.

An amorphous layer is deposited on the gate insulating layer and is patterned by a photolithograph process and an etching process (e.g. dry etching) so that the patterned amorphous layer can comprise a source region, a drain region and a channel region to form the active layer of the TFT. For example, the active layer has a thickness of 100 Å to 3000 Å, and is formed by PECVD, LPCVD or sputtering at a deposition temperature lower than 600° C.

Step 403: forming a mask above the channel region.

A layer of photoresist is applied to the active layer and then is developed after an exposing process is performed with a photo mask to keep the photoresist located above the channel region, which will be used as a mask upon performing ion implanting subsequently.

Step 404: depositing an induction metal layer on the substrate on which the mask is formed.

In this embodiment, Nickel (Ni) is employed to form the induction metal layer, thus it is possible to obtain better induction effect and better TFT properties. However, the induction metal for forming the induction metal layer is not limited to Ni. For example, the induction metal can be one or more from Ni, Copper (Cu), Gold (Au). Silver (Ag), Aluminum (Al), Cobalt (Co), and chromium (Cr). An Ni thin film can be formed by sputtering, thermal evaporation, PECVD, atomic layer deposition (ATM) or the other similar method with a thickness between 1 Å to 10000Å. In this embodiment, the Ni thin film is formed by ALD in order to control the thickness of the Ni thin film more accurately.

Step 405: doping impurity into the source region and the drain region by an ion implanting process so as to bombard part of the induction metal into the source region and the drain region.

It is possible to implant a p-type dopant (B⁺) or an n-type dopant (P⁺) according to the conductive type of TFT (PMOS or NMOS). In this embodiment, the TFT is a PMOS device, and the implanting of B⁺ is performed by using the photoresist as a mask, in which the dose of B+ ranges from 1×10¹⁵ to 1×10¹⁶ atoms/cm³. Since the Ni thin film is dense and thin in thickness, the Ni atoms are directed into the source region and the drain region together with the implanted B. The amount of Ni atoms which are bombarded into the amorphous silicon is extremely small with respect to the amount of atoms in the Ni thin film. In this manner, the effect of remaining Ni atoms to the channel region is reduced significantly after the crystallization of the amorphous silicon.

The ion implanting is one of the common doping technologies. The available ion implanting technology may include ion implanting with a mass synchrometer, ion-cloud implanting, plasma implanting or solid state diffusion implanting without a mass synchrometer. In this embodiment, the ion-cloud implanting is employed.

Step 406: removing the mask and the induction metal layer.

After the implanting of the ion, the photoresist is removed, and the remaining Ni thin film can be removed by etching. For example, in this embodiment, the substrate 1 is dipped into 30% H₂SO₄ solution (for about 30 minutes) so as to remove the remaining Ni thin film completely.

Step 407: performing a thermal treatment to the doped active layer so that the impurity is activated and the metal induced crystallization and the metal induced lateral crystallization occur in the active layer due to the induction metal, converting the amorphous silicon to polysilicon in the source region, the drain region and the channel region of the active layer.

The substrate is placed into an annealing furnace to be subject to an annealing thermal treatment and thus to complete the activation of the impurity and the crystallization of the amorphous silicon at the same time. For example, the annealing temperature ranges from 400° C. to 600° C., and the annealing time ranges from 1 hour to 3 hours. Since the Ni atoms exist in the source and drain regions, upon perform the thermal treatment, firstly, the MIC crystallization is achieved to form the MIC region. Following the MIC crystallization of the source and drain region, the MILC crystallization is achieved in the channel region to form the MILC region. The active layer of the TFT is converted from amorphous silicon to polysilicon.

Step 408: forming a source electrode and a drain electrode.

Specifically, the step 408 may include depositing a source-drain metal film on the active layer; forming a photoresist pattern by a photolithograph process and patterning the source-drain metal film by using a method of wet etching or dry etching with the photoresist patter being used as a mask so as to form a source electrode and a drain electrode.

The second embodiment of the invention is advantageous in the follows aspects.

(1) Since the induction metal is bombarded into the active layer during performing ion implanting, only one thermal treatment to the active layer is required in order to complete the activation of the impurity and the crystallization of the amorphous silicon, and in turn the duration and the costs for manufacturing the polysilicon TFT are reduced; and

(2) The amount of the induction metal which is bombarded into the active layer is extremely small, thus it is possible to decrease the amount of the induction metal remaining in the channel region after the crystallization is completed, and in turn to decrease the leakage current of the polysilicon TFT and improve the electrical properties of the polysilicon TFT.

It should be appreciated that the embodiments described above are intended to illustrate but not limit the present invention. It should be understood by those skilled in the art that the present invention can be modified or substituted equivalently without departing from the spirit and scope of the present invention, and those modification and substitution should be within the scope of the invention.

1. A method for manufacturing a thin film transistor comprising:
depositing an amorphous layer on a substrate, and patterning the amorphous layer so as to form an active layer comprising a source region, a drain region and a channel region;
forming a gate insulating layer and a gate electrode above the channel region;
depositing an induction metal layer on the substrate on which the gate electrode is formed;
doping impurity into the source region and the drain region by an ion implanting process and bombarding part of the induction metal into the source region and the drain region;
removing the induction metal layer;
performing a thermal treatment to the doped active layer so that the impurity is activated and the metal induced crystallization and the metal induced lateral crystallization occur in the active layer due to the induction metal, converting the amorphous silicon to polysilicon in the source region, the drain region and the channel region of the active layer; and
forming a source electrode and a drain electrode.

2. The method according to claim 1, wherein depositing of the amorphous layer on the substrate comprises:
depositing a buffer layer on the substrate and depositing the amorphous layer on the buffer layer.

3. The method according to claim 1, wherein the induction metal comprises one or more selected from Nickel (Ni), Copper (Cu), Gold (Au), Silver (Ag), Aluminum (Al), Cobalt (Co), and chromium (Cr).

4. The method according to claim 1, wherein forming of the source electrode and the drain electrode comprises:
depositing a passivation layer;
forming via holes in the passivation layer so as to expose the source region and the drain region; and
forming the source electrode and the drain electrode which are connected to the source region and the drain region through the via holes respectively.

5. A method for manufacturing a thin film transistor comprising:
forming a gate electrode and a gate insulating layer on a substrate;
forming an amorphous layer on the gate insulating layer, and patterning the amorphous layer so as to form an active layer comprising a source region, a drain region and a channel region;
forming a mask above the channel region;
depositing an induction metal layer on the substrate on which the mask is formed;
doping impurity into the source region and the drain region by an ion implanting process and bombarding part of the induction metal into the source region and the drain region;
removing the mask and the induction metal layer;
performing a thermal treatment to the doped active layer so that the impurity is activated and the metal induced crystallization and the metal induced lateral crystallization occur in the active layer due to the induction metal, converting the amorphous silicon to polysilicon in the source region, the drain region and the channel region of the active layer; and
forming a source electrode and a drain electrode.

6. The method according to claim 5, wherein the induction metal comprises one or more selected from Nickel (Ni), Copper (Cu), Gold (Au), Silver (Ag), Aluminum (Al), Cobalt (Co), and chromium (Cr).

7. The method according to claim 5, wherein forming of the source electrode and the drain electrode comprises:
depositing a source-drain metal film; and
patterning the source-drain metal film to form the source electrode and drain electrode.

8. A thin film transistor comprising a polysilicon active layer, wherein the thin film transistor is manufactured by using the method according to claim 1.
